(19) United States
(12) Patent Application Publication
(10) Pub. No.: US 2002/0048917 A1
(43) Pub. Date: Apr. 25, 2002

(54) SEMICONDUCTOR DEVICE AND METHOD OF FABRICATING SAME

(76) Inventors: MASAHIRO SEKINE, TOKYO (JP); MOTAHARUL KABIR MAZUMDER, TOKYO (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(21) Appl. No.: 09/146,170

(22) Filed: Sep. 3, 1998

(30) Foreign Application Priority Data
Mar. 5, 1998 (JP) P10-53426

(51) Int. Cl. H01L 21/3205; H01L 21/336; H01L 21/8238

(52) U.S. Cl. 438/585; 438/305; 438/231

(57) ABSTRACT

A semiconductor device and a method of fabricating the same which do not require nitrogen ion implantation for preventing boron ions from passing from a gate electrode into a semiconductor substrate are provided. The gate electrode (30) includes a gate insulating film (31) formed on a major surface of the substrate (10), an electrically conductive film (32N) formed on the gate insulating film (31), and an electrically conductive film (32) formed on the conductive film (32N). The conductive film (32N) is formed by annealing in a nitrogen-containing and hydrogen-free atmosphere. Then, the gate insulating film (31) and the conductive film (32) are shaped to form the gate electrode (30) at one time. In a PMOS transistor formation region (110), boron ions are implanted into the substrate (10) using the gate electrode (30) as a mask to form a source region (5) and a drain region (6).

### BACKGROUND OF THE INVENTION

1. Field of the Invention

The present invention relates to a semiconductor device including a PMOS transistor, and a method of fabricating the same. More particularly, the invention relates to the structure of a gate electrode of a PMOS transistor.

2. Description of the Background Art

In the fabrication of a multiplicity of devices such as semiconductor integrated circuits on a semiconductor wafer, a PMOS transistor (FIG. 11) included in each of the devices is formed in such a manner which is described below. First a substrate 10 is prepared comprising a semiconductor wafer 1, and an N well region 11 formed in the semiconductor wafer 1 within a region 110 wherein a PMOS transistor is to be formed (referred to hereinafter as a PMOS transistor formation region 110) which is defined by isolation oxide films 2. Then, a gate electrode 30 comprising a gate insulating film 31 and an electrically conductive film 32 is formed on the N well region 11. Thereafter, implantation of boron using the gate electrode 30 as a mask, formation of sidewalls 4, and implantation of boron again are performed to form a source region 5 and a drain region 6 having an LDD structure.

The above described boron implantation sometimes causes the boron ions to pass through the gate electrode 30 to reach the N well region 11. An experiment was conducted on a structure shown in FIG. 11 including the gate insulating film 31 made of SiON to examine whether or not the boron ions were prevented from passing from the gate electrode 30 into the N well region 11. A multiplicity of structures shown in FIG. 11 each including the gate insulating film 31 made of SiON were prepared. Only half of the multiplicity of structures were annealed at a temperature of 900° C. for thirty minutes for the measurement of dielectric breakdown with time. The results of the experiment are shown in FIG. 12. FIG. 12 illustrates a Weibull distribution plotting a failure rate along the vertical axis versus the time for which a stress voltage is applied (stress application time) along the horizontal axis. The stress is applied to a pad (not shown) connected electrically to the gate electrode 30. The graph of FIG. 12 shows that, when the stress application time is 68 seconds for annealed structure, the failure rate of the annealed structures is about 90 times earlier than that of the unannealed structures. The increase in the thickness of the gate insulating film 31 may decrease the failure rate, but is not permitted in order to achieve the size reduction and high-current drive of MOS transistors. It is, therefore, difficult to prevent the boron ions from passing from the gate electrode 30 into the N well region 11 by using only the thin gate insulating film 31, even if it is made of SiON.

It has been proposed to use the gate electrode 30 containing nitrogen to prevent the boron ions from passing from the gate electrode 30 into the N well region 11. This is accomplished by nitrogen ion implantation into the gate electrode 30 after the completion of the gate electrode 30 which contains no nitrogen and before the above described boron ion implantation.

FIG. 13 shows the nitrogen implantation. An ion beam scans over the wafer so that the nitrogen ions are introduced into the entire wafer. FIG. 14 shows, for example, 25 semiconductor wafers 1 in one lot which are received in a lot case 100. First, the 25 semiconductor wafers 1 are taken out of the lot case 100. Then, nitrogen ions are implanted into one of the 25 semiconductor wafers 1 using an ion implantation system. Thereafter, the nitrogen ion implantation process is performed on the remaining semiconductor wafers 25 one by one in sequential order until the nitrogen ion implantation into all of the 25 semiconductor wafers is completed.

As above described, the ion implantation system is disadvantageous in that it is not capable of implanting the ions at one time into the 25 semiconductor wafers 1 in one lot but is required to implant the nitrogen ions into the wafers 1 one by one in sequential order. This adds to the time and cost required to fabricate semiconductor devices.

Techniques using the CVD process to provide a gate electrode having a nitrogen-containing film solved the above described problems which were disclosed in, for example, Japanese Patent Application Laid-Open No. P08-330584A (1996) and Japanese Patent Application Laid-Open No. P03-181176A (1991). Japanese Patent Application Laid-Open No. P08-330584A discloses a gate electrode including, for example, a nitrogen-containing polycrystalline silicon film formed by the CVD process using silane gas (SiH₄) and ammonia gas (NH₃) or the CVD process using disilane gas (Si₂H₆) and ammonia gas (NH₃). On the other hand, Japanese Patent Application Laid-Open No. P03-181176A discloses a gate electrode including a nitrogen-and-boron-containing silicon film formed by the CVD process using, for example, disilane gas (Si₂H₆) and diborane gas (B₂H₆). Thus, the use of the CVD process allows the introduction of nitrogen ions into a plurality of wafers at one time.

However, such techniques present another problem in that the use of the hydrogen-containing gases for nitrogen introduction create a multiplicity of trap centers resulting from hydrogen in the gate electrode. The result of the multiplicity of trap centers causes an early breakdown of the devices during operation.

### SUMMARY OF THE INVENTION

A first aspect of the present invention is intended for a method of fabricating a semiconductor device. According to the present invention, the method comprises the steps of: (a) forming a gate electrode on a semiconductor substrate; and (b) implantation of boron into the semiconductor substrate using the gate electrode as a mask to form a source region and a drain region, the step (a) comprising the steps of (a-1) forming a gate insulating film on a major surface of the semiconductor substrate, (a-2) forming a first polysilicon film on the gate insulating film, and (a-3) annealing a structure provided in the steps (a-1) and (a-2) in an atmosphere containing nitrogen and free of hydrogen.

Preferably, according to a second aspect of the present invention, in the method of the first aspect, the step (a) further comprises the step of (a-4) forming a second polysilicon film containing a dopant on the first polysilicon film.

Preferably, according to a third aspect of the present invention, in the method of the second aspect, the gate insulating film is made of SiON.

According to a fourth aspect of the present invention, a semiconductor device comprises: a semiconductor substrate; a gate electrode formed on the semiconductor substrate; and a source region and a drain region formed in the semiconductor substrate on opposite sides of the gate electrode, respectively, the gate electrode including a gate insulating film of SiON formed on the semiconductor substrate, a first polysilicon film formed on the gate insulating film and containing nitrogen, and a second polysilicon film formed on the first polysilicon film and free of nitrogen, wherein the source region, the drain region, and the second polysilicon film are doped with boron.

In accordance with the first aspect of the present invention, the annealing in the nitrogen-containing and hydrogen-free atmosphere precludes the generation of trap centers resulting from hydrogen and causes trap centers resulting from other than hydrogen in the first polysilicon film to be saturated by nitrogen. This suppresses the generation of the trap centers which are not saturated by the dopant in the gate electrode. Further, the process for preventing boron ions from the gate electrode into the semiconductor substrate may be performed entirely on a plurality of wafers without the need for the conventional wafer-by-wafer nitrogen ion implantation.

In accordance with the second aspect of the present invention, the second polysilicon film is formed aside from the first polysilicon film containing nitrogen, and the dopant is introduced into the second polysilicon film. This eliminates the need for considering the amount of nitrogen introduced into the first polysilicon film to introduce the dopant into the second polysilicon film, as compared with the direct introduction of the dopant into the first polysilicon film.

In accordance with the third aspect of the present invention, since the gate insulating film also contains nitrogen, the thickness of the first polysilicon film may be reduced.

In accordance with the fourth aspect of the present invention, the gate insulating film and first polysilicon film which contain nitrogen may prevent boron ions in the second polysilicon film from passing through the first polysilicon film and the gate insulating film to reach the semiconductor substrate disposed immediately under the gate insulating film.

It is therefore an object of the present invention to provide a semiconductor device and a method of fabricating the same which involve the implantation of boron using a gate electrode as a mask, which do not require nitrogen ion implantation for preventing the boron ions from passing from the gate electrode into a semiconductor substrate, and which suppress the generation of trap centers that are not saturated by a dopant in the gate electrode.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 through 9 show the steps of fabricating a semiconductor device according to a preferred embodiment of the present invention;

FIG. 10 is a sectional view of the semiconductor device according to the preferred embodiment of the present invention;

FIG. 11 is a sectional view of a conventional semiconductor device;

FIG. 12 is a graph showing a failure rate due to dielectric breakdown;

FIG. 13 shows the step of fabricating a conventional semiconductor device; and

FIG. 14 shows semiconductor wafers received in a lot case.

### DESCRIPTION OF THE PREFERRED EMBODIMENTS

With reference to FIGS. 1 through 10, a semiconductor device and a method of fabricating the same according to a preferred embodiment of the present invention will now be described using as an example a dual-gate MOS transistor which enables low-voltage operation.

First, a substrate 10 formed using techniques well known in the art is prepared (FIG. 1). The substrate 10 is constructed such that an N well region 11 and a P well region 12 are formed on an upper surface of a semiconductor wafer 1 within a PMOS transistor formation region 110 and an NMOS transistor formation region 120, respectively, which are defined by isolation oxide films 2.

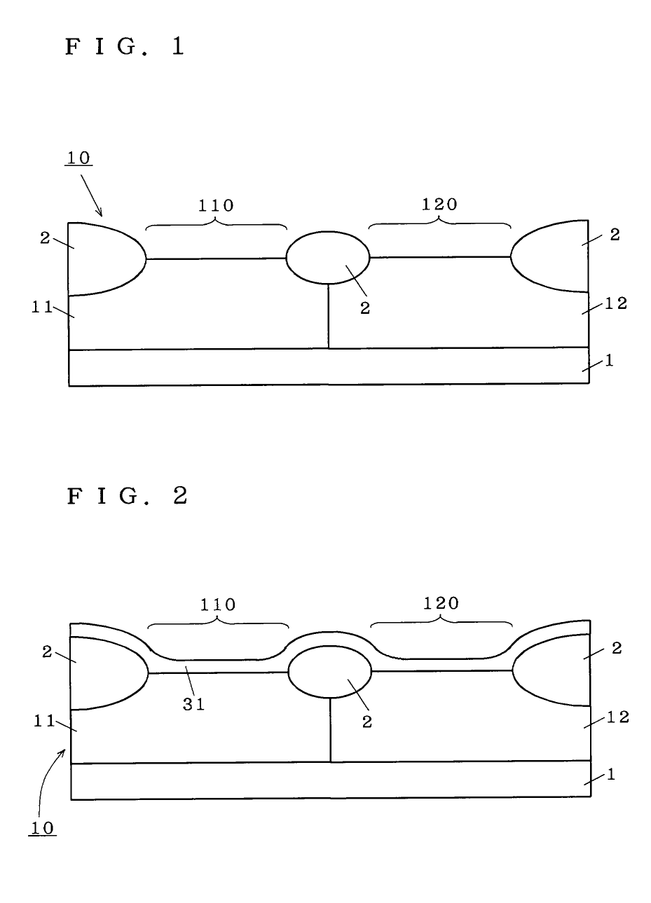

Then, a gate insulating film 31 is formed on a major surface of the substrate 10 (FIG. 2).

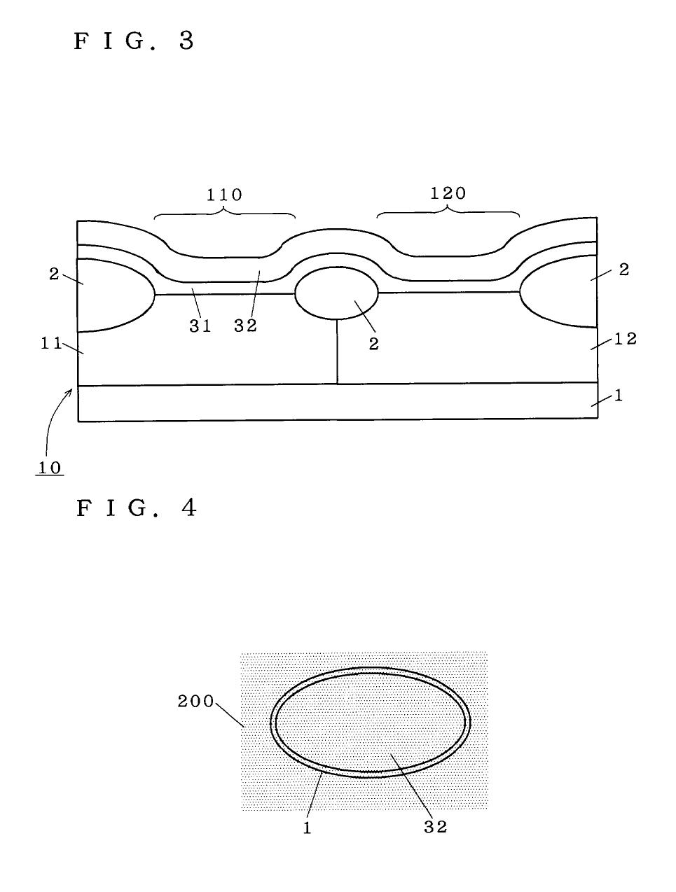

Next, an electrically conductive film 32 made of polysilicon in which no impurities are implanted, or undoped polysilicon, is formed on the gate insulating film 31, but the formation of the conductive film 32 is once suspended (FIG. 3). The conductive film 32 shown in FIG. 3 corresponds to a first polysilicon film.

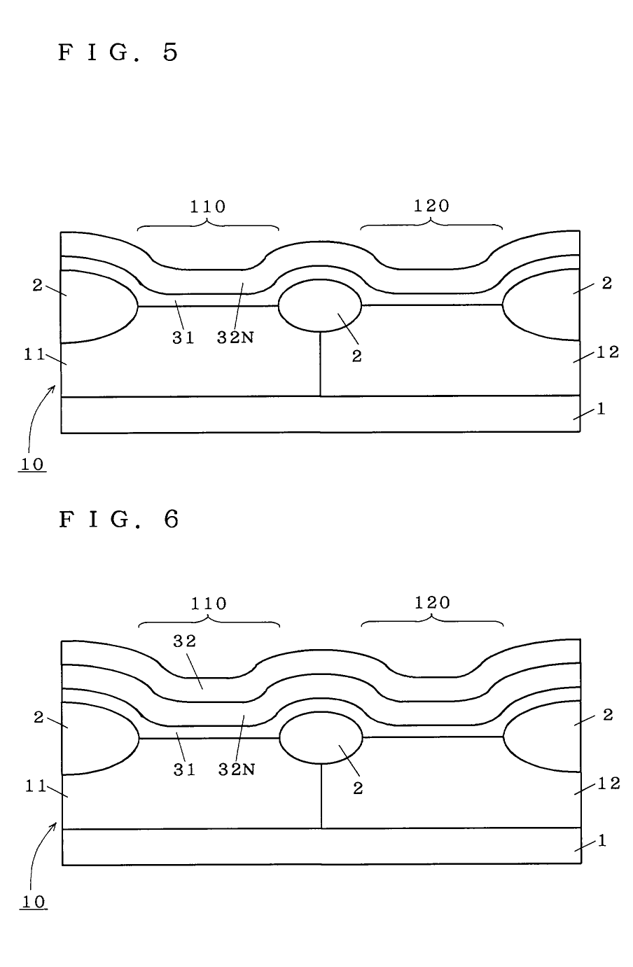

The resultant structure is annealed by means of an annealing system in an atmosphere 200 of N₂O gas or NO gas under conditions of 900° C. for ten minutes or under conditions of 800° C. for thirty minutes (FIG. 4). As a result, the conductive film 32 is changed into a nitrogen-containing electrically conductive film 32N (FIG. 5).

The use of hydrogen-containing gases for formation of a nitrogen-containing film creates a large number of trap centers resulting from hydrogen in the conductive film 32N as in the techniques disclosed in Japanese Patent Application Laid-Open No. P08-330584A and Japanese Patent Application Laid-Open No. P03-181176A. On the other hand, since the atmosphere 200 is free of hydrogen, no trap centers resulting from hydrogen are formed in the conductive film 32N. Although trap centers resulting from other than hydrogen are generated, the trap centers are saturated by nitrogen and, therefore, the resistance in the conductive film 32N is decreased.

The reasons for the annealing under the above described conditions are as follows: in the atmosphere 200 of N₂O gas or NO gas, nitrogen is not diffused in the undoped conductive film 32 at a temperature of 700° C. or lower, and desired electrical characteristics of elements formed in a region not shown are not provided at a temperature above 900° C.

After the completion of the formation of the conductive film 32N, the atmosphere 200 is changed from the N₂O gas or NO gas to a gas for a dopant (for example, PH₃ gas). Then, the formation of the conductive film 32 is started again. At the same time that the conductive film 32 grows, annealing is performed at an appropriate temperature using the annealing system (FIG. 6). Since the trap centers generated in the conductive film 32 are saturated by the dopant, the resistance in the conductive film 32 is decreased. The conductive film 32 shown in FIG. 6 corresponds to a second polysilicon film.

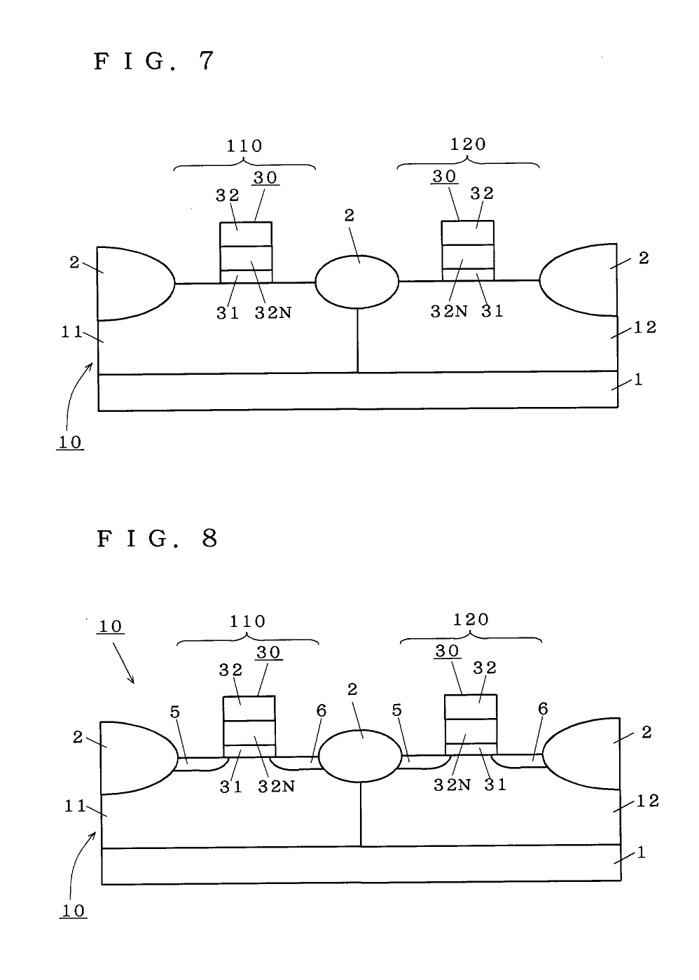

Then, parts of the gate insulating film 31, the conductive film 32N and the conductive film 32 are selectively removed and shaped using the photolithographic and etching techniques well known in the art. Consequently, gate electrodes 30 are formed respectively in the PMOS transistor formation region 110 and the NMOS transistor formation region 120, with the substrate 10 exposed on opposite sides of each of the gate electrodes 30 (FIG. 7).

In the PMOS transistor formation region 110, boron ions are implanted using the gate electrode 30 as a mask to form a source region 5 and a drain region 6 in the N well region 11 respectively on opposite sides of the gate electrode 30. Then, the gate electrode 30 in the PMOS transistor formation region 110 contains boron, and the conductive film 32 contains boron but does not contain nitrogen. In the NMOS transistor formation region 120, on the other hand, phosphorus ions are implanted using the gate electrode 30 as a mask to form a source region 5 and a drain region 6 in the P well region 12 respectively on opposite sides of the gate electrode 30 (FIG. 8).

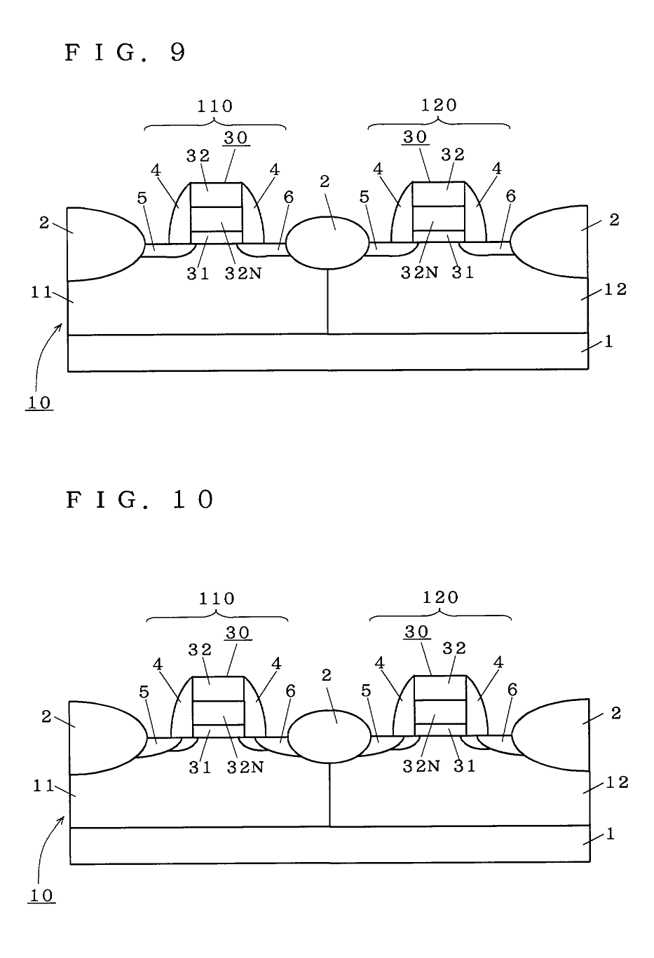

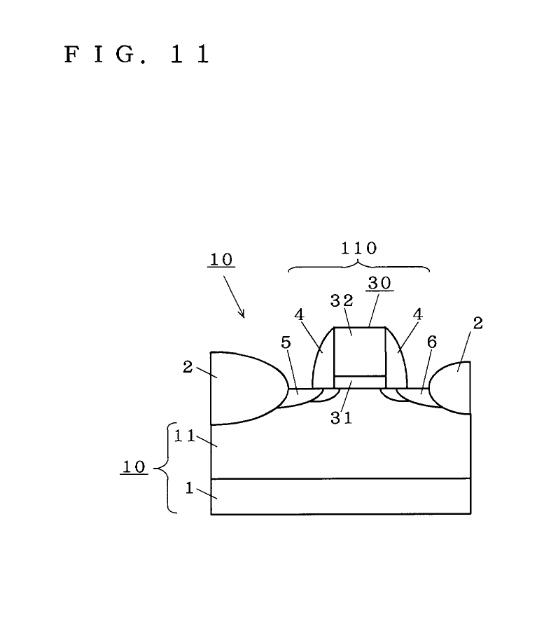

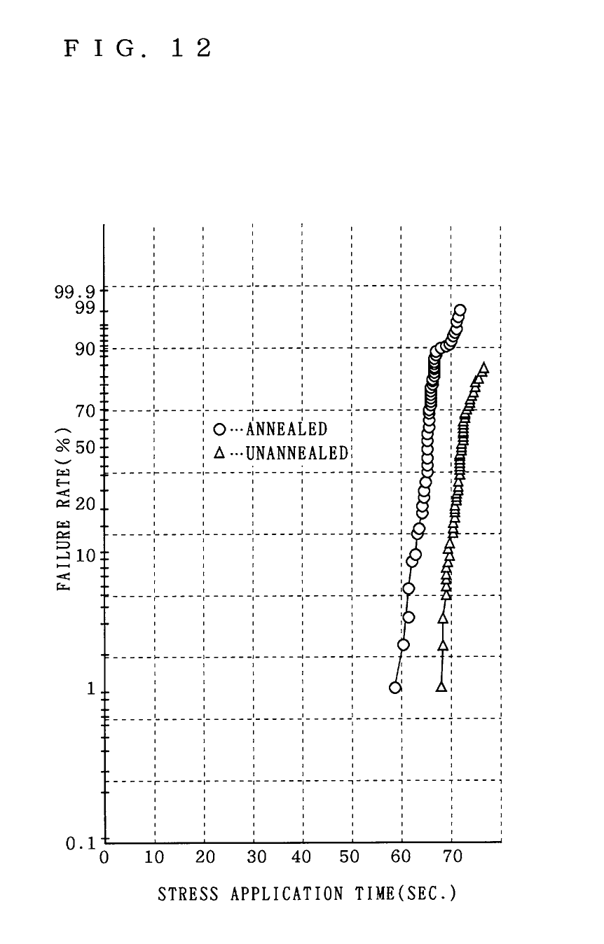

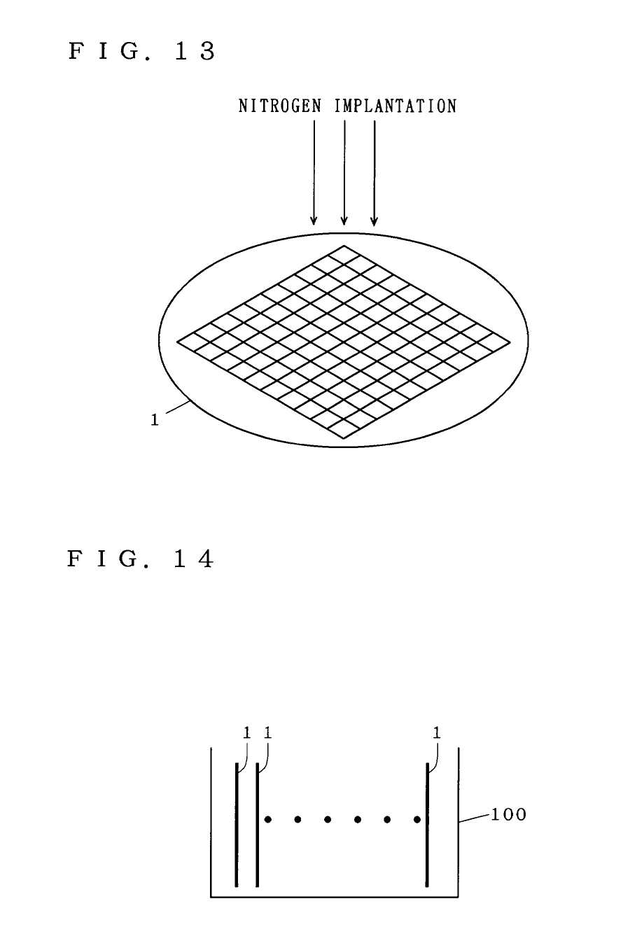

Sidewalls 4 for the gate electrodes 30 are formed (FIG. 9). Again, boron ions are implanted into the source region 5 and the drain region 6 in the PMOS transistor formation region 110 whereas phosphorus ions are implanted into the source region 5 and the drain region 6 in the NMOS transistor formation region 120, thereby causing the source regions 5 and the drain regions 6 to have the LDD structure. This simultaneously completes dual-gate MOS transistors shown in FIG. 10 in great numbers (including those not shown) on the semiconductor wafer 1.

The preferred embodiment of the present invention provides effects to be described below. The method of fabricating the semiconductor device according to the preferred embodiment comprises implanting boron ions using the gate electrode 30 as a mask, but does not require the conventional wafer-by-wafer nitrogen ion implantation for preventing the boron ions from passing from the gate electrode 30 into the N well region 11 which has been discussed in the description of the background art. This achieves the reductions in time and cost required to fabricate semiconductor devices.

Additionally, the use of the nitrogen-containing and hydrogen-free gas for formation of the nitrogen-containing film precludes the generation of the trap centers resulting from hydrogen. The trap centers resulting from other than hydrogen are saturated by nitrogen. This suppresses the generation of the trap centers which are not saturated by the dopant in the gate electrodes.

Suspending the formation of the conductive film 32 for annealing in the nitrogen-containing atmosphere facilitates the formation of the conductive film 32N.

Further, after the annealing in the atmosphere 200 of N₂O gas or NO gas, annealing may be performed in the atmosphere 200 of the gas for the dopant by using a chamber and the annealing system which have been used for the former annealing.

The annealing may be performed at one time upon a plurality of semiconductor wafers.

Insulating films of SiO₂, SiON and the like may be used as the gate insulating film 31. If the insulating film of SiON is employed which is less pervious to boron because it contains nitrogen, the conductive film 32N may be of a thickness ranging from about 400 angstroms to about 600 angstroms. This contributes to size reduction. If the thickness of the conductive film 32N is less than about 400 angstroms, boron ions can pass from the gate electrode 30 into the N well region 11. If the thickness of the conductive film 32N is greater than about 600 angstroms, interconnections are difficult to form because of the level difference between the substrate 10 and the top of the gate electrodes 30, and capacitances and resistances parasitic on the gate are increased.

The formation of the two conductive films, that is, the nitrogen-containing conductive film 32N and the dopant-containing conductive film 32 on the gate insulating films 30 eliminates the need for considering a nitrogen content to provide the dopant, as compared with the direct introduction of the dopant into the conductive film 32N.

The gas used for forming the conductive film 32N may be any nitrogen-containing and hydrogen-free gas, in addition to the N₂O gas or NO gas. The substrate 10 may be of construction other than that shown in FIG. 1.

While the invention has been described in detail, the foregoing description is in all aspects illustrative and not restrictive. It is understood that numerous other modifications and variations can be devised without departing from the scope of the invention.

We claim:

1. A method of fabricating a semiconductor device, comprising the steps of:
(a) forming a gate electrode on a semiconductor substrate; and
(b) implanting boron into said semiconductor substrate using said gate electrode as a mask to form a source region and a drain region,
said step (a) comprising the steps of
(a-1) forming a gate insulating film on a major surface of said semiconductor substrate,
(a-2) forming a first polysilicon film on said gate insulating film, and
(a-3) annealing a structure provided in said steps (a-1) and (a-2) in an atmosphere containing nitrogen and free of hydrogen.

2. The method according to claim 1,
wherein said step (a) further comprises the step of
(a-4) forming a second polysilicon film containing a dopant on said first polysilicon film.

3. The method according to claim 2,
wherein said gate insulating film is made of SiON.

4. A semiconductor device comprising:
a semiconductor substrate;
a gate electrode formed on said semiconductor substrate; and
a source region and a drain region formed in said semiconductor substrate on opposite sides of said gate electrode, respectively,
said gate electrode including
a gate insulating film of SiON formed on said semiconductor substrate,
a first polysilicon film formed on said gate insulating film and containing nitrogen, and
a second polysilicon film formed on said first polysilicon film and free of nitrogen,
wherein said source region, said drain region, and said second polysilicon film are doped with boron.
